(19) United States
(12) Patent Application Publication
(10) Pub. No.: US 2023/0402298 A1
(43) Pub. Date: Dec. 14, 2023

(54) APPARATUS FOR CLEANING POT-SHAPED HOLLOW BODIES, IN PARTICULAR TRANSPORT CONTAINERS FOR SEMICONDUCTOR WAFERS OR FOR EUV LITHOGRAPHY MASKS

(71) Applicant: PACE-TEC GMBH, Furtwangen (DE)

(72) Inventors: Gunter HAAS, St. Georgen (DE); Jürgen GUTEKUNST, Steckborn (CH); Frank SCHIENLE, Freiburg (DE)

(21) Appl. No.: 18/035,217

(22) PCT Filed: Nov. 5, 2021
(86) PCT No.: PCT/EP2021/080793

§ 371 Date: May 3, 2023

(30) Foreign Application Priority Data
Nov. 9, 2020 (DE) 10 2020 129 469.7

(51) Int. Cl. H01L 21/67; H01L 21/033; H01L 21/311; G03F 1/24; G03F 1/82

(52) U.S. Cl. CPC H01L 21/67051; H01L 21/0337; H01L 21/31144; G03F 1/24; G03F 1/82

(57) ABSTRACT

An apparatus for cleaning pot-shaped hollow bodies, in particular transport containers for semiconductor wafers or for EUV lithography masks includes a support wall onto which the hollow body can be placed by way of its edge surface, a locking device by means of which the hollow body can be sealingly and releasably connected to the support wall, a passage opening which is formed by the support wall and is arranged radially within the locking device, a cleaning device by means of which a first cleaning fluid can by dispensed for cleaning the hollow body inner surface when the hollow body is connected to the support wall and a first discharge channel with a first end. The first discharge channel is in fluidic communication with the passage opening and with which the first cleaning fluid dispensed by the cleaning device can be discharged.

### CROSS-REFERENCE TO RELATED APPLICATIONS

This application is a Section 371 of International Application No. PCT/EP2021/080793, filed Nov. 5, 2021, which was published in the German language on May 12, 2022 under International Publication No. WO 2022/096657 A1, which claims priority under 35 U.S.C. § 119(b) to German Application No. 10 2020 129 469.7, filed Nov. 9, 2020, the disclosures of which are incorporated herein by reference in their entireties.

### BACKGROUND OF THE INVENTION

The preferred present invention relates to a device for cleaning pot-shaped hollow bodies, in particular transport containers for semiconductor wafers or for extreme ultraviolet radiation (“EUV”) lithography masks.

The manufacture of highly integrated electronic circuits and other sensitive semiconductor components takes place today in factories in which so-called semiconductor wafers run through a large number of processing steps. A large part of these processing steps takes place in clean rooms that are kept free of contaminants, in particular free of particles, with a high effort. Such a complex processing is necessary since particles that come into contact with the semiconductor material of the semiconductor wafers can in particular influence the material properties of the semiconductor wafers such that a total production batch becomes defective and unusable and has to be scrapped.

Since keeping clean is becoming more and more important as the integration density of the semiconductor circuits and the effort to keep clean increase exponentially as the size of the clean rooms increases, the semiconductor wafers are not transported from one processing station to the next in an “open” state. Special transport containers (so-called FOUPs, front opening unified pods) are used instead. They are understood as box-shaped transport containers into which a large number of semiconductor wafers is inserted. The FOUPs are typically closed by a removable cover. Without the cover the FOUPs have a pot-shaped basic shape with a rectangular base surface. When the FOUPs are closed by their covers, the inserted semiconductor wafers can be transported from one clean room to another clean room protected from the environment. When the FOUPs have reached a processing station, they are opened, the semiconductor wafers are removed, and are processed accordingly. After processing has taken place, the semiconductor wafers are transported back into the FOUPs and are then conveyed to the next processing station.

Due to the high production downtimes on contaminations of the semiconductor wafers, it is necessary to clean the FOUPs from time to time. The FOUPs are in particular contaminated by the wear debris of the semiconductor wafers on the introduction into and the removal from the FOUPs.

The same applies accordingly to the transport containers for EUV lithography masks (“extreme ultraviolet radiation”). The EUV lithography masks are used to manufacture very small integrated circuits. The EUV lithography masks, like the semiconductors, also have to be transported, with a similar situation arising. When FOUPs are spoken of in the following, the statements in this respect apply equally to transport containers for EUV lithography masks.

Devices for cleaning FOUPs are known, for example, from U.S. Pat. No. 5,238,503 A, International Patent Application Publication No. WO 2005/001888 A2, and European Patent No. EP 1 899 084 B1.

With such cleaning devices, the FOUPs are cleaned both on both their inner surfaces and their outer surfaces. The FOUPs are typically contaminated much more strongly on their outer surfaces than on their inner surfaces. As a result, the cleaning fluid accumulates both particles that originate from the outer surfaces and particles than originate from the inner surfaces during the cleaning procedure. The particles can therefore be transported from the outer surfaces to the inner surfaces. A satisfactory cleaning result is, however, only achieved when the number of particles has fallen below a certain value. Due to the particles originating from the outer surface, the cleaning procedure has to be carried out for a correspondingly long time period to be able to remove a sufficient portion of the particles. This is disadvantageous to the extent that, on the one hand, the amount of the required cleaning fluid is comparatively high and, on the other hand, the FOUPs cannot be used to transport the semiconductor wafers during the cleaning process. The production of the semiconductor wafers is hereby made more expensive. There is additionally the fact that a cleaning of the outer surface only contributes to the reduction of defective semiconductor wafers with limitations.

### BRIEF SUMMARY OF THE INVENTION

It is the object of an embodiment of the preferred present invention to propose a device for cleaning pot-shaped hollow bodies by which they can be cleaned with simple and inexpensive means within a short time.

This object is achieved by the features specified in the present disclosure. Advantageous embodiments are the subject matter of the embodiments described in the present disclosure.

An embodiment of the preferred invention relates to a device for cleaning pot-shaped hollow bodies, in particular transport containers for semiconductor wafers or for EUV lithography masks, wherein the hollow body comprises:
a base wall and one or more side walls that form an inner hollow body surface; and
has an opening that is disposed opposite the base wall and that is surrounded by a marginal surface;
   wherein the device comprises:
a support wall on which the marginal surface of the hollow body can be placed;
a locking device by which the hollow body is sealingly connectable to the marginal surface and releasably connectable to the support wall; and
at least one passage opening that is formed by the support wall and that is arranged radially within the locking device;
a cleaning device by which a first cleaning fluid for cleaning the inner hollow body surface can be dispensed when the hollow body is connected to the support wall; and
a first drainage channel having a first end, wherein the first end of the first drainage channel is only in fluid communication with the passage opening and by which the first cleaning fluid dispensed by the cleaning device can be drained.

The marginal surface of the hollow body is placed onto the support wall for cleaning, with the opening of the hollow body and the passage opening of the support wall being directly adjacent to one another. It is therefore possible to introduce the first cleaning fluid into the hollow body and thus to clean the inner hollow body surface. The first cleaning fluid cannot exit the inner space of the hollow body due to the fact that the locking device is configured such that the marginal surface of the hollow body is not only fixed, but also sealed, with respect to the support wall. The first cleaning fluid can consequently not be soiled by particles that are located outside the hollow body. The first cleaning fluid consequently only serves the cleaning of the inner hollow body surface that, as initially mentioned, is typically considerably less contaminated than the outer hollow body surface. The first cleaning fluid is consequently not contaminated by the particles originating from the outer hollow body surface, whereby the inner hollow body surface is effectively cleaned. The marginal surface represents the dividing section between the inner hollow body surface and the outer hollow body surface when the hollow body has been placed onto the support wall. The sealing of the hollow body with respect to the support wall also takes place at the marginal surface. The time period that is required to clean the inner hollow body surface can be considerably reduced in comparison with devices known from the prior art. In addition, the amount of the first cleaning fluid that is necessary to clean the inner hollow body surface is likewise reduced.

In accordance with a further embodiment, the first end of the first drainage channel is connected to the support wall and surrounds the passage opening. In this embodiment, the construction effort required to provide the device can be kept small. The first drainage channel can in particular either be produced integrally with the support wall or connected to it by welding, for example.

In a further developed embodiment, the first drainage channel can expand in a funnel like manner toward the first end. Diameter differences between the passage opening and the first drainage channel can be compensated in a simple manner due to the funnel like expansion of the first drainage channel toward the first end. The construction effort is hereby kept small. In addition, no abrupt diameter jumps occur that can result in disruptions to the flow in the form of eddies, for example. These disruptions can result in a particle deposition, whereby the drainage of the particles can be slowed down or fully interrupted and the cleaning of the inner hollow body surface can be disadvantageously influenced.

In a further development embodiment, the first drainage channel can terminate flush with the passage opening at the first end. No dead spots arise in which particles can be deposited, whereby the cleaning of the inner hollow body surface can be disadvantageously influenced.

In a further embodiment, the cleaning device can have a first cleaning head that projects over the passage opening. In this embodiment, the first cleaning head can be introduced into the inner space of the hollow body. As a consequence, the distance between the first cleaning head and the inner hollow body surface can be reduced. The pressure at which the cleaning fluid exits the first cleaning head also acts on the inner hollow body surface with only a small loss, whereby the particles located on the inner hollow body surface can be particularly effectively removed.

A further developed embodiment is characterized in that the first cleaning head is rotationally and/or translationally movable. It is possible to react to geometrical special features of the inner hollow body surface due to the movability of the first cleaning head. It is in particular possible to apply the first cleaning fluid at least approximately perpendicular to the inner hollow body surface, whereby the kinetic energy of the first cleaning fluid can be particularly effectively used to clean the inner hollow body surface.

In accordance with a further developed embodiment, the first cleaning head has a number of first cleaning nozzles via which the first cleaning fluid can be dispensed at a spray angle, with the first cleaning head having a setting device by which the spray angle can be set. The spray angle at which the first cleaning fluid is dispensed also determines the angle at which the cleaning fluid impinges on the inner hollow body surface. An angle of 90° or of approximately 90° is ideal. Due to the fact that the spray angle can be set, the geometry of the inner hollow body surface can be modeled in that the first cleaning fluid can be applied almost over the total inner hollow body surface at an angle of 90° or approximately 90°. The inner hollow body surface typically has labyrinthine points so that shading can occur with non-adjustable cleaning nozzles in which no amount or only a limited amount of the first cleaning fluid can be applied to the inner hollow body surface with sufficient kinetic energy. Such shading can be avoided in this embodiment so that the cleaning result is improved overall.

A further developed embodiment can specify that the first cleaning nozzles can be opened and closed independently of one another. If one of the first cleaning nozzles is open, the first cleaning fluid can be dispensed, which is not possible in the closed state. It is thus possible to clean the inner hollow body surface such that initially the sections that are clean in accordance with expectations are cleaned first and the more soiled sections are only subsequently cleaned. The charging of the first cleaning fluid with particles released from the inner hollow body surface can hereby be kept as low as possible. It is in particular hereby prevented that comparatively clean sections are cleaned by the first cleaning fluid that already has a high charge. In a number of cases, the absorption capability of the first cleaning fluid for particles drops as the charge increases. In an extreme case, deposits of particles from the first cleaning fluid on a comparatively clean section of the inner hollow body surface can occur. This can be prevented by a corresponding control of the first cleaning nozzles.

In addition, only specific sections of the inner hollow body surface can be cleaned and the number of particles taken up can be counted. This counting of the particles can be repeated so often that representative statements are possible. It can hereby be determined whether an above average number of particles are applied to the inner hollow body surface in a specific manufacturing process of the semiconductor wafers. Conclusions on specific defects or on improvement potentials of the manufacturing process can be drawn from this.

An embodiment is characterized in that the device has at least one coupling unit to couple sound waves into the first cleaning fluid. In this respect, the sound waves can in particular be ultrasound waves or megasound waves. While ultrasound waves have a frequency range of approximately 20 kHz to 500 kHz depending on the definition, megasound waves have a frequency range of approximately 500 kHz to 3 MHz. It appears sensible here to wet the inner hollow body surface completely with the first cleaning fluid or to flood the total space surrounded by the inner hollow body surface and to couple the sound waves into the first cleaning fluid. The first cleaning fluid then serves as a carrier of the sound waves. The cleaning effect is increased due to the fact that a specific amount of energy is hereby carried into the first cleaning fluid since particles adhering to the inner hollow body surface can hereby be particularly easily released. The energy input increases with the frequency of the sound coupled in. On the use of megasound, the advantage results that the energy can be brought to the inner hollow body surface to be cleaned in a very targeted manner so that good cleaning results can be achieved.

In a further developed embodiment, at least some of the coupling units can be integrated in at least some of the first cleaning nozzles or can interact therewith. In this case, the cleaning nozzles can be designed as so-called “megasonic nozzles” that make it possible to couple the sound waves into the first cleaning fluid dispensed by the first cleaning nozzles. It is then no longer necessary to wet the total inner hollow body surface with the first cleaning fluid, whereby the amount of the required first cleaning fluid can be kept small.

In accordance with a further embodiment, the cleaning device has a supply channel for supplying the first cleaning fluid to the first cleaning head, with the first drainage channel and the supply channel being combined at least sectionally to form a fluid conducting unit. In this respect, however, the supply channel and the drainage channel remain fluidically separate. The supply channel and the drainage channel can here be formed as pipework and/or as tubes. Construction space can be saved and the device can thus be designed as compact due to the combination of the first drainage channel and the supply channel to form a fluid conducting unit. In addition, the manufacturing effort can be kept small since the number of components of the device can be reduced.

In accordance with a further embodiment, a first channel is arranged in the support wall by which a flushing fluid can be conducted to the marginal surface. In particular nitrogen or compressed air, and particularly preferably extreme clean dried air, also called XCDA, is used as the flushing fluid. It is hereby prevented that the first cleaning fluid can move over the marginal surface onto the outer hollow body surface where it can mix with a second cleaning fluid. It is moreover prevented that the second cleaning fluid can move over the marginal surface onto the inner hollow body surface where it can mix with the first cleaning fluid. Contaminations are thus prevented.

A further embodiment is characterized in that a particle measuring device is arranged in the first drainage channel to determine the particles contained in the first cleaning fluid. The particle measuring device can be designed, for example, such that the number of particles that pass through the particle measuring device on a given volume flow of the first cleaning fluid is determined. If the number of counted particles falls below a certain value, it can be assumed that the inner hollow body surface has been sufficiently cleaned. It is ensured by the particle measuring device, on the one hand, that the inner hollow body surface has actually been cleaned to a sufficient degree; on the other hand, the cleaning procedure can be aborted in this case. In the devices known from the prior art, the cleaning procedure is carried out for so long until it can be assumed with a sufficient likelihood that the hollow bodies have been sufficiently cleaned. In most cases, the cleaning procedure is carried out considerably longer than necessary for safety reasons. Since it is possible in accordance with the present embodiment to abort the cleaning procedure as described, both the time period and the amount of the first cleaning fluid are reduced so that the cleaning procedure can be carried out overall considerably more effectively than in the prior art. In addition, the particle measuring device also permits a documentation that a specific FOUP has actually been cleaned to a sufficient degree.

In accordance with a further developed embodiment, the hollow body has a cover that has an inner cover surface and an outer cover surface and by which the opening can be closed. In this respect, a cleaning opening that is at least partially closable by a closure body is arranged in the support wall or in a further wall section, with the closure body having a reception unit for receiving the cover of the hollow body and the cleaning device having a further first cleaning head by which the first cleaning fluid can be applied to the inner cover surface for cleaning when the cleaning opening is closed by the closure body or by the cover.

The previously described embodiments of the device relate to the cleaning of the inner hollow body surface. As mentioned, the FOUPs can be closed by a removable cover. Particles that can have a negative effect on the manufacture of the semiconductor wafers can, however, collect just as easily on the inner cover surface as on the inner hollow body surface. In this embodiment, however, the device comprises a further first cleaning head by which the inner cover surface can be cleaned. The same first cleaning fluid is used for this purpose that is also used for cleaning the inner hollow body surface. A further cleaning fluid can, however, also be used if this appears necessary. The particles on the inner cover surface can thus likewise be removed. To prevent the uncontrolled discharge of the first cleaning fluid from the cleaning opening, the cleaning opening has to be sealingly closed during the cleaning process. For this purpose, either the cover or the closure body interacts with the support wall or the further wall section such that the cleaning opening is sealingly closed. In this respect, the cleaning opening can be arranged such that no particles can move from the environment of the hollow body into the first cleaning fluid during the cleaning process. It appears sensible here to drain the first cleaning fluid via the first draining channel. The reception unit of the closure body here interacts with the outer cover surface so that the inner cover surface is in particular accessible for the first cleaning fluid without obstacle.

A further embodiment specifies that the closure body is movably fastened to the support wall or to the further wall section between an open position in which the closure body releases the cleaning opening and a closure position in which the closure body closes the cleaning opening. In this embodiment, the closure body can be particularly easily integrated into the handling of the cover. In the open position, a robot gripper or the like can introduce the cover into the reception unit of the closure body. The reception unit is equipped with fixing means by which the cover can be releasably fastened to the closure body. Once the robot gripper has placed down the cover and the cover has been fastened to the closure body, the closure body is moved into the closure position. The cleaning opening is sealingly closed in the closure position so that the cleaning process with respect to the inner cover surface can be started. After the end of the cleaning processes, the closure body is again moved into the open position and the connection between the closure body and the cover is released so that the robot gripper can remove the cover from the reception unit. It appears sensible here to fasten the closure body rotatably to the support wall or to the further wall section.

A further embodiment provides that the device can have a second channel by which a flushing fluid can be conducted to the cover. The cover of a transport container typically has a cover seal by which the cover can be sealed with respect to the remainder of the transport container. In particular nitrogen or compressed air, and particularly preferably extreme clean dried air, also called XCDA, is used as the flushing fluid.

An exact bounding of the effective area of the first cleaning fluid by which the inner cover surface is cleaned can be effected by the flushing fluid. The boundary can be selected here such that the first cleaning fluid cannot reach the cover seal. It is hereby prevented that particles that are located in the first cleaning fluid can adhere to the seal, can release from the seal in operation of the transport container, and can damage semiconductor wafers. If a gas is used, a turbulent flow is generated that promotes an effective blowing off or cleaning of the seal.

In accordance with a further embodiment in which the base wall and the side wall form an outer hollow body surface, the cleaning device has a second cleaning head by which a second cleaning fluid can be released for cleaning the outer hollow body surface. In this respect, the device has a second drainage channel by which the second cleaning fluid dispensed by the second cleaning head unit can be drained. As initially mentioned, it is not absolutely necessary to also clean the outer hollow body surface. This can nevertheless be desired to keep the particle concentration in the clean rooms small, for example. In this embodiment, a cleaning of the outer hollow body surface is possible, with the second cleaning fluid being drained separately from the first cleaning fluid. A mixing of the first cleaning fluid and the second cleaning fluid and an increase in the particle concentration with the particles originating from the outer hollow body surface that results herefrom is prevented, which is not possible with the devices from the prior art. It is consequently also prevented in the event that both the inner hollow body surface and the outer hollow body surface are cleaned that particles that originate from the outer hollow body surface can move onto the inner hollow body surface. The cleaning process of the inner hollow body surface is consequently not negatively influenced by the particles that originate from the outer hollow body surface.

The particle concentration on the inner hollow body surface is typically smaller than on the outer hollow body surface. The separate drainage of the first cleaning fluid and the second cleaning fluid makes possible the reuse of the first cleaning fluid for cleaning the outer hollow body surface. In this respect, the charge (or particle concentration) in the first cleaning fluid can first be determined to decide whether the charge of the first cleaning fluid is small enough to be able to clean the outer hollow body surface to the required extent. If this is possible, the quantity of the cleaning fluid and consequently the cleaning costs can be kept small.

In a further developed embodiment, the device can have a housing that surrounds a process space together with the outer wall, with the process space being accessible via a housing opening closable by a covering. The hollow body can be introduced into the process space and removed again through the housing opening. It is possible in this embodiment to conduct the second cleaning fluid in a defined manner and to avoid its uncontrolled distribution in the device.

In a further developed embodiment, the support wall can have a number of passage bores, with the passage bores being arranged radially outside the locking device and by which the second drainage channel is fluidically connected to the process space. Depending on the embodiment of the hollow bodies, the passage bores can also be designed as passage slits. The second cleaning fluid can be removed from the process space via the second drainage channel in a controlled manner without the second cleaning fluid mixing with the first cleaning fluid.

A further developed embodiment is characterized in that the second cleaning head is in U shape and is rotationally and/or translationally movable in the process space. The second cleaning fluid can be conducted both to the base wall and to the side walls due to the U shape of the second cleaning head. It is possible to react flexibly to geometrical special features of the outer hollow body surface to be cleaned due to the movability of the second cleaning head.

In accordance with a further embodiment, the first cleaning head, the further first cleaning head, and/or the second cleaning head have at least one drying nozzle and/or an infrared diode. In this embodiment, the device according to the proposal can be used not only for cleaning, but also for the subsequent drying of the hollow body. To conclude the cleaning process, the supply of the first cleaning fluid or of the first and second cleaning fluids is stopped and instead a drying gas, air or nitrogen, for example, is conveyed through the fluid conducting unit by which the hollow body is dried. For this purpose, the hollow body has a correspondingly formed connector, in particular a vacuum connector, via which a vacuum can be generated within the hollow body to suck the drying gas into the hollow body and to subsequently remove it from it again. A pipe, also called a snorkel, is connected to this connector and can, for example, be connected to a vacuum pump. The position of the hollow body in the device remains unchanged here. Both the inner hollow body surface and the outer hollow body surface can be dried depending on the embodiment. In this case, no mixing takes place of the drying gas that is used for the inner hollow body surface with the drying gas that is used for the outer hollow body surface.

It is possible in another respect to also equip the second cleaning nozzles and the second cleaning head with the same features as the first cleaning nozzles and the first cleaning head, and vice versa, if this is expedient.

Alternatively or accumulatively, infrared diodes can be used that have the advantage that the radiation that is output by infrared diodes is in a tightly restricted frequency range that is optimized toward the cleaning fluid used. The residues of the cleaning fluid still remaining on the inner hollow body space or on the outer hollow body space are very effectively heated and thus eliminated.

An embodiment of the preferred invention relates to the use of a device in accordance with one of the above embodiments for cleaning transport containers for semiconductor wafers. The technical effects and advantages that can be achieved with the use according to the proposal correspond to those that have been discussed for the present device. It must be pointed out in summary that the time duration that is required to clean the inner hollow body surface can be considerably reduced in comparison with devices known from the prior art.

In addition, the amount of the first cleaning fluid that is necessary to clean the inner hollow body surface is likewise reduced. These advantages apply to a particular degree to the manufacture of semiconductor wafers.

An embodiment of the preferred invention relates to a method of cleaning pot-shaped hollow bodies, in particular transport containers for semiconductor wafers or for EUV lithography masks, using a device in accordance with one of the previous embodiments, said method comprising the following steps:
placing the marginal surface of the hollow body onto the support wall;
sealingly and releasably connecting the hollow body to the support wall by means of the locking device, with the hollow body being sealed with respect to the support wall at the marginal surface;
   dispensing a first cleaning fluid for cleaning the inner hollow body surface by means of the first cleaning head of the cleaning device and draining the first cleaning fluid by means of the first drainage channel; and/or
   dispensing a second cleaning fluid for cleaning the outer hollow body surface by means of the second cleaning head of the cleaning device and draining the second cleaning fluid by means of the second drainage channel.

The technical effects and advantages that can be achieved with the method according to the proposal correspond to those that have been discussed for the present device. It must be pointed out in summary that the inner hollow body surface and the outer hollow body surface can be cleaned independently of one another. A contamination of the first cleaning fluid that is used for cleaning the inner hollow body surface with particles that have been removed from the outer hollow body surface is precluded. It is additionally possible with the method according to the proposal either only to clean the outer hollow body surface or only to clean the inner hollow body surface if this is desired. The outer hollow body surface can furthermore be cleaned for a shorter time than the inner hollow body surface. It is furthermore also possible to clean both the outer hollow body surface and the inner hollow body surface simultaneously.

In accordance with a further embodiment, the method can comprise the following steps:
moving the closure body into the open position;
placing the outer cover surface of the cover onto the reception unit of the closure body and releasably fastening the cover to the closure body;
moving the closure body into the closure position; and
dispensing the first cleaning fluid for cleaning the inner cover surface by the further first cleaning head.

The cover can be placed on the reception unit by means of a robot gripper, for example. The reception unit is easily accessible in the open position so that the placing and removing of the cover can take place quickly and simply without the robot gripper having to perform complicated movements. The conducting of the first cleaning fluid is ensured in the closure position so that a mixing with the second cleaning fluid is avoided for the reasons named above. It must be noted that the device according to the proposal can also be operated such that only the cover is cleaned and not the hollow body. In this case, the passage opening can be closed by a closure element.

A further development specifies that the method comprises the following steps:
completely flooding the space bounded by the inner hollow body surface by the first cleaning fluid; and
coupling sound waves into the first cleaning fluid by means of a coupling unit.

The sound waves can, for example, be coupled in the form of ultrasound or megasound. The cleaning result is improved hereby since energy is hereby introduced into the first cleaning fluid and serves the release of the particles on the inner hollow body surface. The inner cover surface and the outer hollow body surface can be handled accordingly.

According to a further developed embodiment, the method comprises the following steps:
coupling sound waves into the first cleaning fluid dispensed by the first cleaning nozzle by means of a coupling unit, with the coupling unit being integrated in the first cleaning nozzle or interacting therewith.

The sound waves can also be coupled in as ultrasound or megasound in this embodiment. The cleaning result is also improved in this embodiment for the reasons named above. However, since no flooding of the space bounded by the inner hollow body surface is necessary in this embodiment, the required amount of the first cleaning fluid can be kept correspondingly small. The inner cover surface and the outer hollow body surface can be handled accordingly.

### BRIEF DESCRIPTION OF THE SEVERAL VIEWS OF THE DRAWING

The foregoing summary, as well as the following detailed description of the preferred invention, will be better understood when read in conjunction with the appended drawings. For the purpose of illustrating the preferred invention, there are shown in the drawings embodiments which are presently preferred. It should be understood, however, that the invention is not limited to the precise arrangements and instrumentalities shown. In the drawings:

FIG. 1 is a basic cross-sectional representation through a preferred embodiment of a device for cleaning pot-shaped hollow bodies, in particular transport containers for semiconductor wafers or for EUV lithography masks;

FIG. 2 is an enlarged representation, not to scale, of the detail A defined within the dashed box in FIG. 1; and

FIG. 3 is an enlarged representation, not to scale, of the detail B defined within the dashed box in FIG. 1.

### DETAILED DESCRIPTION OF THE INVENTION

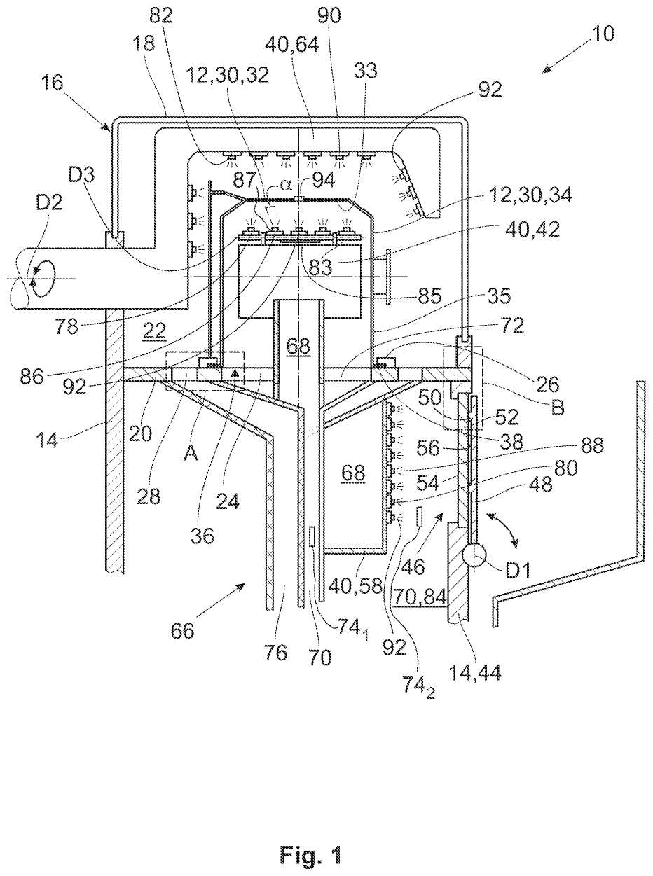

An embodiment of a device 10 according to the proposal for cleaning pot-shaped hollow bodies 12 is shown with reference to a basic sectional representation in FIG. 1. The device 10 has a housing 14 that forms a housing opening 16 that is closable by a covering 18 removable from the housing 14. A support wall 20 is furthermore arranged in the housing 14 so that a closed process space 22 is provided in the housing 14. The process space 22 is bounded by the support wall 20, by the housing 14 itself, and by the covering 18. The support wall 20 forms a passage opening 24, with a locking device 26 being arranged radially outside the passage opening 24. Two passage bores 28 are provided in the support wall 20 radially outside the locking device 26 in the embodiment shown.

With a removed covering 18, a hollow body 12, in particular a transport container 30 for semiconductor wafers, also called a FOUP, or a transport container 30 for EUV lithium masks, can be introduced into the process space 22. The hollow body 12 has a base wall 23 and, in this case, four side walls 34 so that the pot-shaped hollow body 12 is substantially parallelepiped-shaped. It is, however, by all means possible to provide the pot-shaped hollow body with a different geometry, for example a cylindrical geometry. The base wall 32 and the four side walls 34 form an inner hollow body surface 33 and an outer hollow body surface 35.

The hollow body 12 has an opening 36 that is arranged disposed opposite the base wall 32 and that is surrounded by a marginal surface 38 that is formed by the side walls. The hollow body 12 is designed in the manner of a flange in the region of the marginal surface 38 in the embodiment shown. The marginal surface 38 of the hollow body 12 can be placed onto the support wall 20. The passage opening 24 of the support wall 20 and the opening 36 of the hollow body 12 are at least approximately of the same size and of the same geometrical shape in the embodiment shown.

The locking device 26 is furthermore configured such that the passage opening 24 is at least approximately flush with the section of the inner hollow body surface 33 adjoining the passage opening 24.

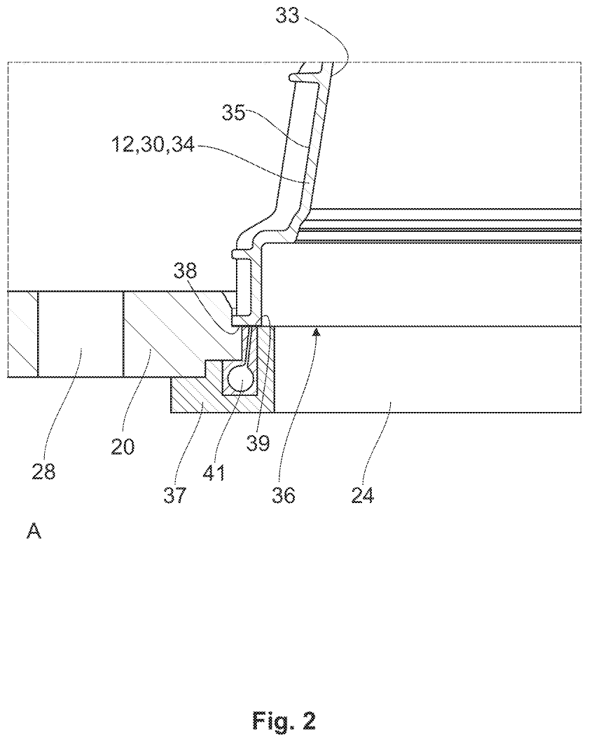

The region A marked in FIG. 1 is not shown enlarged to scale in FIG. 2, with no exact agreement being present. For illustration reasons, the locking device 26 is not shown. It can be recognized from FIG. 2 that the support wall 20 comprises a support wall section 37 that forms a contact surface 39 that is in contact with the marginal surface 38 of the transport container 30. In this respect, the contact surface 39 of the support wall section 37 is completely covered by the marginal surface 38. A first channel 41 is arranged in the support wall section 37 that opens into the contact surface 39 and by which a flushing fluid, for example air or nitrogen, can be conducted to the marginal surface 38.

The device 10 is furthermore equipped with a cleaning device 40 that has a first cleaning head 42, that projects over the passage opening 24, and that is thus arranged within the process space 22. When the hollow body 12 is connected to the support wall 20, the first cleaning head 42 is surrounded by the hollow body 12.

The housing 14 further comprises a wall section 44 in which a cleaning opening 46 is arranged. The wall section 44 is located at the side of the side wall 20 remote from the locking device 26. The cleaning opening 46 is at least partially closable by a closure body 48 that is rotatably fastened to the wall section 44 about a first axis of rotation D1 by a drive unit, not shown. The closure body 48 can be moved between an open position in which the closure body 48 releases the cleaning opening 46 and a closure position in which the closure body 48 at least partially closes the cleaning opening 46. The closure body 48 is in the closure position in FIG. 1.

The closure body 48 has a reception nit 50 by which a cover 52 by which the hollow body 12 is closable can be releasably fastened to the closure body 48. The cover 52 forms an inner cover surface 54 and an outer cover surface 56. The inner cover surface 54 is here that side of the cover 52 that directly adjoins the inner hollow body surface 33 when the hollow body 12 has been closed by the cover 52. In other words, the inner cover surface 54 in this case faces toward the base wall 32 of the hollow body 12.

The reception unit 50 is designed in the-embodiment shown such that it only interacts with the cover 52 by means of the outer cover surface 56.

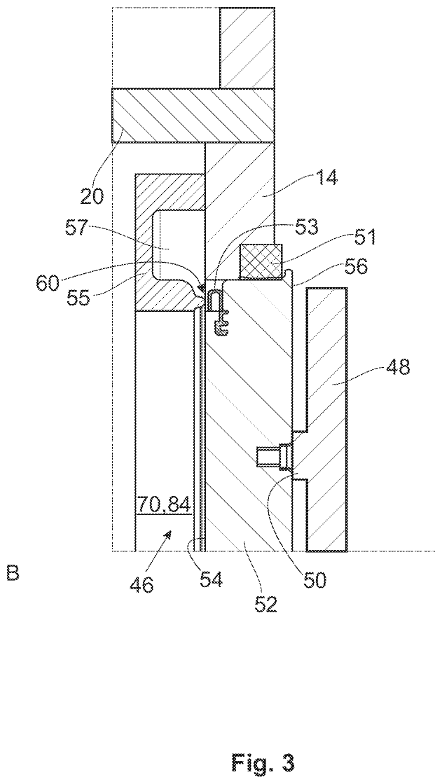

The region B marked in FIG. 1 is not shown enlarged to scale in FIG. 3, with no exact agreement being present. It can be recognized that a housing seal 51 is arranged adjacent to and surrounding the cleaning opening 45. If the closure body 48 is in the closure position, the cover 52 interacts with the housing seal 51. The cleaning opening 46 is to this extent closed and sealed by means of the cover 52. The statement according to which the closure body 48 at least partially closes the cleaning opening 46 is to be understood against this background. It is, however, also conceivable that the closure body 48 interacts with the housing seal 51 and completely sealingly closes the cleaning opening 46.

It can furthermore be recognized from FIG. 3 that the cover 52 has a cover seal 53 by which the transport container 30 can be sealingly closed when the cover 52 has been connected to the transport container 30. A channel element 55 is furthermore arranged at the housing 14 that, together with the housing 14, forms a second channel 57 by which a flushing fluid, for example air or nitrogen, can be conducted to the cover 52. The channel element 55 is designed such that it forms a gap 60 with the cover seal 53.

The cleaning device 40 is additionally equipped with a further first cleaning head 58 that is arranged in the vicinity of the closure body 48 when it is in the closure position.

The cleaning device 40 moreover comprises a second cleaning head 64 that is substantially formed in U shape and is at least partially arranged in the process space 22. Unlike the first cleaning head 42, however, the second cleaning head 64 is arranged outside the hollow body 12 when the hollow body 12 is connected to the support wall 20 as shown in FIG. 1. The second cleaning head 64 is rotatable about a second rotational axis D2, with the drive device used for this purpose not being shown. An embodiment is furthermore not shown in which the second cleaning head 64 is not only rotationally movable, but also translationally or only translationally. In the embodiment shown, the first cleaning head 42 is not movable; however, it can also be designed as rotationally and/or translationally movable.

The device 10 is furthermore provided with a fluid conducting unit 66 by which a first cleaning fluid can be conducted to the first cleaning head 52 and to the further first cleaning head 58 and a second cleaning fluid can be conducted to the second cleaning head 64. The fluid conducting element 66 has a first supply channel 68 by which the first cleaning fluid can be conducted to the first cleaning head 42.

A detailed representation of a second supply channel for supplying the second cleaning fluid to the second cleaning head 64 has been dispensed with for illustration reasons, but its design should be easily deducible for the skilled person.

The fluid conducting unit 66 furthermore comprises a first drainage channel 70 by which the first cleaning fluid dispensed by the first cleaning head 42 and by the further first cleaning head 58 can be drained from the process space 22 again. The first drainage channel 70 has a first end 72 that is in fluid communication with the passage opening 24. As can be seen from FIG. 1, the first drainage channel 70 is expanded in funnel shape toward the first end 72 and is connected to the support wall 20 such that the first end 72 of the drainage channel terminates flush with the passage opening 24.

A first particle measuring device 741 is arranged in the first drainage channel 70 by which the particles that are in the first cleaning fluid and originate from the inner hollow body surface 33 can be determined and in particular counted. A second particle measuring device 742 is moreover arranged in the secondary channel 742 by which the particles that are in the first cleaning fluid and originate from the inner hollow body surface 54 can be determined and in particular counted.

The fluid conducting unit 66 furthermore has a second drainage channel 76 that is designed substantially exactly the same as the first drainage channel 70; however, with the two passage bores 28 being in fluid communication. In this respect, the first drainage channel 70 forms the radially inner wall of the second drainage channel 76 so that the fluid conducting unit 66 can have a very compact design. An embodiment is not shown in which a further particle measuring device 74 is arranged in the second drainage channel 76. It must be pointed out at this point that the fluid conducting unit 66 is only shown in principle in FIG. 1. The representation of the fluid conducting unit 66 in accordance with FIG. 1 does not make any claims of correctness due to the large number of channels arranged nested and at different levels. The skilled person will, however, be able to at least deduce a functional design of the fluid conducting unit 66 without problem from FIG. 1.

The device 10 is operated in the following manner: In the starting state, not shown here, the cover 18 is open and the second cleaning head 64 is rotated by 90° with respect to FIG. 1 so that the U-shaped section of the second cleaning head 64 is perpendicular to the plane of FIG. 1. The closure body 48 is in the open position in which the closure body 48 is aligned approximately horizontally with respect to FIG. 1.

The cover 52 is separated from the hollow body 12 and placed onto the reception unit 50 by a handling device, not shown, for example by a robot gripper. The open hollow body 12 is introduced into the process space 22 such that the marginal surface 38 of the hollow body 12 lies on the support wall 20, as is shown in FIG. 1. The hollow body 12 is subsequently locked by the locking unit 26 so that it is connected to the support wall 20 and is thus fixed in the process space 22. In this respect, the locking device 26 is equipped with sealing agents, not shown here, so that the hollow body 12 is sealed with respect to the support wall 20. The cover 18 is now closed. In addition, the reception unit 50 of the closure body 48 is activated so that the cover 52 is fixed to the closure body 48. The closure body 48 is rotated by 90° into the closure position, as is shown in FIG. 1. The cover 52 here seals the cleaning opening 46.

A first cleaning fluid is now conducted over the first supply channel 68 to the first cleaning head 42 and is dispensed by first cleaning nozzles 78 such that the inner hollow body surface 33 is cleaned by the first cleaning fluid. The further first cleaning head 58 has further first cleaning nozzles 80 by which the first cleaning fluid is applied to the inner cover surface 54 that is consequently cleaned.

At the same time, a second cleaning fluid that can correspond to the first cleaning fluid is conducted via the second supply channel, not shown here, to the second cleaning head 64 where the second cleaning fluid is dispensed by second cleaning nozzles 82 to clean the outer hollow body surface 35. In this respect, the second cleaning head 64 can be rotated about the second rotational axis D2.

The first cleaning nozzles 78, the further first cleaning nozzles 80, and the second cleaning nozzles 82 can be configured such that the spray angle α at which the first cleaning fluid and the second cleaning fluid are dispensed is settable. For this purpose, the first cleaning nozzles 78, the further first cleaning nozzles 80, and the second cleaning nozzles 82 can be supported in spherical head shape. Alternatively or accumulatively, in particular the first cleaning nozzles 78 can be arranged on a tube body 83 rotatable about a third rotational axis D3 so that the spray angle α can be set. The first cleaning head 58 at least comprises a setting device 85 by which the spray angle α can be set. The further first cleaning nozzles 80 and the second cleaning nozzles 80 can be correspondingly formed, with the spray angle α at which the first cleaning fluid is dispensed by the further first cleaning nozzles 80 is likewise set by the setting device 85. The setting device 85 can also be configured such that the spray angle α of the second cleaning nozzles 80 located on the second cleaning head 64 can likewise be set. It can hereby be achieved that the first cleaning fluid and the second cleaning fluid impinge perpendicular or almost perpendicular on the inner hollow body surface 33 and on the inner cover surface or the outer hollow body surface 35.

The device 10 furthermore has at least one coupling unit 87 for coupling sound waves into the first cleaning fluid. In this respect, the coupling unit 87 can also be configured such that the sound waves can also be coupled into the second cleaning fluid. In the embodiment shown, some of the coupling units 87 are integrated in at least some of the first cleaning nozzles 78 and are designed as so-called “megasonic nozzles”. A megasonic wave can be coupled into the first cleaning fluid dispensed by the first cleaning nozzles 78. The same can correspondingly be provided for the further first nozzles 80 and the second cleaning nozzles 82.

The first cleaning nozzles 78 can be opened and closed independently of one another. It is consequently possible to clean different sections of the inner hollow body surface 33 first and other sections later. For example, sections that are less soiled according to experience can be cleaned first and sections that are more soiled according to experience can be subsequently cleaned. The further first cleaning nozzles 80 and the second cleaning nozzles 82 can be designed correspondingly such that the first inner cover surface 54 and the outer hollow body surface 35 can be correspondingly cleaned.

At the same time, a flushing fluid is conducted through the first channel 41 to the marginal surface 38 and/or through the second channel 57 to the cover 52. It can be the same flushing fluid here, but it is also possible to conduct a first flushing fluid through the first channel 41 and a second flushing fluid different from the first flushing fluid through the second channel 57. The flushing fluid that is conducted through the first channel 41 to the marginal surface 38 provides that neither the first cleaning fluid nor the second cleaning fluid can traverse the marginal surface. The flushing fluid therefore effects a fluidic seal between the first cleaning fluid and the second cleaning fluid. It is consequently ensured that the first cleaning fluid and the second cleaning fluid cannot mix. A contamination of the first cleaning fluid by the second cleaning fluid and vice versa is prevented.

The first cleaning fluid that has been dispensed by the first cleaning head 42 and has been applied to the inner hollow body surface 33 is supplied via the first drainage channel 70. The same also applies to the first cleaning fluid that has been dispensed by the further first cleaning head 58 and has been applied to the inner cover surface 54. The first drainage channel 70 has a secondary channel 84 that opens into the first drainage channel 70 to drain the first cleaning fluid that is used to clean the inner cover surface 54.

The flushing fluid that is conducted to the cover 52 flows through the gap 60 back into the secondary channel 84. The housing seal 51 prevents the flushing fluid from being able to enter into the environment. It is prevented by the flushing fluid that the first cleaning fluid that has been dispensed by the further first cleaning head 58 and has been applied to the inner cover surface 54 can reach the cover seal 53 to which particles in the first cleaning fluid can adhere.

The flushing fluid that is conducted to the marginal surface 38 and/or to the cover 52 can be placed under a sufficiently large pressure.

Particles that were located on the inner hollow body surface 33 and on the inner cover surface 54 are removed by the first cleaning fluid. The particles that originate from the inner hollow body surface 33 are detected by the first particle measuring device 741 and the particles that originate from the inner cover surface 54 are detected by the second particle measuring device. In this respect, the first particle measuring device 741 and the second particle measuring device 742 are configured such that the number of particles that pass through the particle measuring device 74 at a given volume flow within a certain time is determined. It can hereby be determined whether the inner hollow body surface 33 and the inner cover surface 54 have been cleaned to the desired degree or not. If, for example, the inner hollow body surface 33 is sufficiently clean, the cleaning process for the hollow body 12 can be aborted while the cleaning process for the inner cover surface 54 is continued. In the meantime, the hollow body 12 can be removed from the device by the robot gripper, whereby time can be saved.

As mentioned, a further particle measuring device 74 can be arranged in the second drainage channel 76. The particles that originate from the outer hollow body surface 35 can be detected by this further particle measuring device. This information can also be integrated in the decision whether the cleaning process for the hollow body 12 can be aborted or not. If the charge of the first cleaning fluid with particles originating from the inner hollow body surface 33 does not exceed a specific value, it can also be used for the cleaning of the outer hollow body surface 35.

An embodiment is not shown in which the particle measuring device 74 is arranged downstream of the opening of the secondary channel 84 into the first drainage channel 70. In this case, no distinction can be made whether the particles have originated from the inner cover surface 54 or from the inner hollow body surface 33. The cleaning process can nevertheless be aborted when the number of particles falls below a certain degree.

The second cleaning fluid that has been dispensed by the second cleaning head 64 and has been applied to the outer hollow body surface 35 is drained via the second drainage channel 76. Consequently, the first cleaning fluid and the second cleaning fluid are drained separately from one another as a result of which particles that originate from the outer hollow body surface 35 cannot enter into the first cleaning fluid and thus not onto the inner hollow body surface 33 or onto the inner cover surface 54.

The cleaning of the inner hollow body surface 33 and of the inner cover surface 54 generally has a greater importance than the cleaning of the outer hollow body surface 35. If it is found that the inner hollow body surface 33 and the inner cover surface 54 have been cleaned to the desired degree, the cleaning process can be aborted independently of the degree to which the outer hollow body surface 35 has been prepared.

A first drying gas and a second drying gas, for example air or nitrogen, can now be conducted via the first supply channel 68 or via the second supply channel in largely the same manner as the first and second cleaning fluids to the first cleaning head 52, to the further first cleaning head 58, and to the second cleaning head 64. A vacuum is, however, generated in the hollow body 12 for this purpose in that a pipe, not shown, is connected to a vacuum connector 94 and can be connected to a vacuum pump, likewise not shown. The first drying gas and/or the second drying gas is/are sucked into the hollow body 12 as a result of the vacuum and subsequently removed from the hollow body 12 again. The first cleaning head 42 has first drying nozzles 86, the further first cleaning head 84 has further first drying nozzles 88, and the second cleaning head has second drying nozzles 90 by which the first drying gas or the second drying gas can be dispensed and applied to the inner hollow body surface 33, to the inner cover surface 54, and to the outer hollow body surface 35. The first drying gas and the second drying gas displace the first cleaning fluid and the second cleaning fluid from the device 10. Residues of the first and second cleaning fluids can moreover be blown away.

The first cleaning head 42, the further first cleaning head 58, and the second cleaning head can furthermore each be heated via infrared diodes 92 by which residues of the first and second cleaning fluids can be heated and vaporized, as a result of which they can be removed from the device 10 by the first and second drying gases.

After the termination of the drying process, the covering 18 is opened and the closure body 48 is moved into the open position. The cleaned hollow body 12 is removed from the process space. The reception unit 50 is deactivated, as a result, the cover 52 can be removed from the closure body 48 and supplied to the hollow body 12 for the closing thereof.

A further hollow body 12 to be cleaned can now be handled in the described manner in the device 10.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

### REFERENCE NUMERAL LIST

10 device
12 hollow body
14 housing
16 housing opening
18 covering
20 support wall
22 process space
24 passage opening
26 locking device
28 passage bore
30 transport container
32 base wall
33 inner hollow body surface
34 side wall
35 outer hollow body surface
36 opening
38 marginal surface
40 cleaning device
42 first cleaning head
44 wall section
46 cleaning opening
48 closure body
50 reception unit
52 cover
54 inner cover surface
56 outer cover surface
58 further first cleaning head
64 second cleaning head
66 fluid conducting unit
68 first supply channel
70 first drainage channel
72 first end
74 particle measuring device
76 second drainage channel
78 first cleaning nozzle
80 further first cleaning nozzles
82 second cleaning nozzles
83 tubular body
84 secondary channel
85 setting device
86 first drying nozzles
87 coupling unit
88 further first drying nozzles
90 second drying nozzles
92 infrared diodes
94 vacuum connector
α spray angle
D1 first rotational axis
D2 second rotational axis

1-24. (canceled)

25. A device for cleaning a pot-shaped hollow body, in particular transport containers for semiconductor wafers or for EUV lithography masks, the hollow body comprising:
a base wall and a side wall that forms an inner hollow body surface;
an opening that is disposed opposite the base wall and that is proximate a marginal surface of the side wall;
a support wall on which the marginal surface of the hollow body can be placed;
a locking device by which the hollow body is sealingly connectable to the marginal surface and releasably connectable to the support wall;
a passage opening that is formed by the support wall and that is arranged radially inwardly from the locking device;
a cleaning device by which a first cleaning fluid for cleaning the inner hollow body surface can be dispensed when the hollow body is connected to the support wall; and
a first drainage channel having a first end, wherein the first end of the first drainage channel is only in fluid communication with the passage opening and by which the first cleaning fluid dispensed by the cleaning device can be drained, wherein the cleaning device has a first cleaning head that projects over the passage opening and the first cleaning head has a number of first cleaning nozzles by which the first cleaning fluid can be dispensed at a spray angle, wherein the first cleaning head has a setting device by which the spray angle can be set.

26. The device in accordance with claim 25, wherein the first end of the first drainage channel is connected to the support wall and surrounds the passage opening.

27. The device in accordance with claim 25, wherein the first drainage channel expands in the manner of a funnel toward the first end.

28. The device in accordance with claim 25, wherein the first drainage channel terminates flush with the passage opening at the first end.

29. The device in accordance with claim 25, wherein the first cleaning head is rotationally and/or translationally movable.

30. The device in accordance with claim 25, further comprising:
a coupling unit for coupling sound waves into the first cleaning fluid.

31. The device in accordance with claim 30, the coupling units is integrated in at least some of the number of first cleaning nozzles or interact therewith.

32. The device in accordance with claim 25, wherein the cleaning device has a supply channel for supplying the first cleaning fluid to the first cleaning head, wherein the first drainage channel and the supply channel are combined at least sectionally to form a fluid conducting unit.

33. The device in accordance with claim 25, wherein a first channel is arranged in the support wall by which a flushing fluid can be conducted to the marginal surface.

34. The device in accordance with claim 25, wherein a particle measuring device for determining particles contained in the first cleaning fluid is arranged in the first drainage channel.

35. The device in accordance with claim 25, wherein the hollow body has a cover having an inner cover surface and an outer cover surface by which the opening is closable, wherein a cleaning opening is arranged in the support wall or in a further wall section that is at least partially closable by a closure body, with the closure body having a reception unit for receiving the cover of the hollow body; and—the cleaning device has a second cleaning head by which the first cleaning fluid can be applied to the inner cover surface for cleaning when the cleaning opening is closed by the closure body or by the cover.

36. The device in accordance with claim 35, wherein the closure body is movably fastened to the support wall or to the further wall section between an open position in which the closure body releases the cleaning opening and a closure position in which the closure body or the cover closes the cleaning opening.

37. The device in accordance with claim 35, wherein the device has a second channel by which a flushing fluid can be conducted to the cover.

38. The device in accordance with claim 25, wherein the base wall and the side wall form an outer hollow body surface, wherein the cleaning device has a second cleaning head by which a second cleaning fluid for cleaning the outer hollow body surface can be dispensed; and the device has a second drainage channel by which the second cleaning fluid dispensed from the second cleaning head can be drained.

39. The device in accordance with claim 38, wherein the device has a housing that surrounds a process space together with the support wall, with the process space being accessible via a housing opening closable by a covering.

40. The device in accordance with claim 39, wherein the support wall has a number of passage bores, with the number of passage bores being arranged radially outside the locking device and by which the second drainage channel is fluidically connected to the process space.

41. The device in accordance with claim 39, wherein the second cleaning head has a U shape and is rotationally and/or translationally movable in the process space.

42. The device in accordance with claim 38, wherein the first cleaning head, a further cleaning head, and/or the second cleaning head have at least one drying nozzle and/or an infrared diode.

43. A method of cleaning pot-shaped hollow bodies, in particular transport containers for semiconductor wafers or for EUV lithography masks, using a device in accordance with claim 25, said method comprising the following steps:
placing the marginal surface of the hollow body onto the support wall;
sealingly and releasably connecting the hollow body to the support wall by means of the locking device, with the hollow body being sealed at the marginal surface with respect to the support wall;
dispensing a first cleaning fluid for cleaning the inner hollow body surface by means of a first cleaning head of the cleaning device, wherein the first cleaning head has a number of first cleaning nozzles via which the first cleaning fluid is dispensed at a spray angle, with the first cleaning head having a setting device by which the spray angle can be set; and draining the first cleaning fluid by means of the first drainage channel; and/or
dispensing a second cleaning fluid for cleaning an outer hollow body surface by means of a second cleaning head and draining the second cleaning fluid by means of a second drainage channel.

44. The method in accordance with claim 43, wherein said method comprises the following steps:
moving a closure body into an open position;
placing an outer cover surface of a cover onto a reception unit of the closure body and releasably fastening the cover to the closure body;
moving the closure body into a closure position; and
dispensing the first cleaning fluid for cleaning an inner cover surface by a further cleaning head.

45. The method in accordance with claim 43, said method comprises the following steps:
completely flooding a space bounded by the inner hollow body surface with the first cleaning fluid; and
coupling sound waves into the first cleaning fluid by means of a coupling unit.

46. The method in accordance with claim 43, said method comprises the following steps:
coupling of sound waves into the first cleaning fluid dispensed by a first cleaning nozzle by means of a coupling unit, with the coupling unit being integrated in the first cleaning nozzle or interacting therewith.
